(19) United States
(12) Patent Application Publication
(10) Pub. No.: US 2025/0259823 A1
(43) Pub. Date: Aug. 14, 2025

(54) BROADBAND MICROWAVE RESONANT ANTENNA

(71) Applicant: Applied Materials, Inc., Santa Clara, CA (US)

(72) Inventors: XIAOKANG YANG, Fremont, CA (US); SATHYA GANTA, Sunnyvale, CA (US); KENNETH DOERING, San Jose, CA (US); SANJEEV BALUJA, Campbell, CA (US); JOHN FORSTER, Santa Clara, CA (US)

(21) Appl. No.: 18/438,315

(22) Filed: Feb. 9, 2024

(51) Int. Cl. H01J 37/32

(52) U.S. Cl. CPC H01J 37/32247; H01J 37/3222

(57) ABSTRACT

Embodiments disclosed herein include dielectric resonators for microwave plasma application. In an embodiment, such an apparatus comprises a dielectric puck, where the dielectric puck has a cylindrical shape. In an embodiment, the dielectric puck comprises a first region with a first dielectric constant, and a second region with a second dielectric constant that is different than the first dielectric constant. In an embodiment, the dielectric puck further comprises a hole into a top surface of the dielectric puck.

### BACKGROUND

### 1) Field

Embodiments relate to the field of semiconductor manufacturing and, in particular, apparatuses and methods for providing broadband microwave resonant antennas for plasma processing operations.

### 2) Description of Related Art

Microwave plasma sources are capable of providing high power densities. However, the operational windows for existing microwave plasma sources are narrow. Particularly, the resonant antenna for the plasma source is tuned for specific operating conditions. That is, a single type of plasma is enabled with limited functionality to modify gas pressure, temperature, power, frequency, gas species, or the like. Changing the parameters too much may result in high reflected power. This limitation may be attributable to the resonant antenna operating at a single resonance mode with a narrow impedance bandwidth.

Due to the limited flexibility in existing microwave plasma sources, extensive redesign is needed for each application space. For example, a plasma enhanced chemical vapor deposition (PEVCD) tool and a plasma enhanced atomic layer deposition (PEALD) tool may require different resonant antenna designs. Further, simply changing process conditions within a single type of tool can lead to poor performance.

### SUMMARY

Embodiments disclosed herein include dielectric resonators for microwave plasma application. In an embodiment, such an apparatus comprises a dielectric puck, where the dielectric puck has a cylindrical shape. In an embodiment, the dielectric puck comprises a first region with a first dielectric constant, and a second region with a second dielectric constant that is different than the first dielectric constant. In an embodiment, the dielectric puck further comprises a hole into a top surface of the dielectric puck.

Embodiments disclosed herein may also include an apparatus that comprises a dielectric puck, where the dielectric puck has a cylindrical shape, and a recess into a top surface of the dielectric puck. In an embodiment, the recess is ring shaped and defines an inner region of the dielectric puck and an outer region of the dielectric puck. In an embodiment, the apparatus further comprises a hole into the top surface of the dielectric puck, where the recess surrounds the hole.

Embodiments disclosed herein may also comprise a plasma processing tool. In an embodiment, the tool may comprise a chamber, a pedestal in the chamber, a dielectric plate opposite from the pedestal, and a dielectric puck over the dielectric plate. In an embodiment, the dielectric puck comprises a material composition with a non-uniform dielectric constant in a radial direction and/or a thickness direction. A hole is provided into the dielectric puck. In an embodiment, the tool further comprises an electrically conductive rod inserted into the hole.

### BRIEF DESCRIPTION OF THE DRAWINGS

FIG. 1 is a graph of the reflected power for a single mode resonant antenna and a dual mode resonant antenna, which illustrates a larger bandwidth and lower reflected power in the dual mode resonant antenna solution, in accordance with an embodiment.

FIG. 2A is a plan view illustration of a resonant antenna with a dielectric puck, in accordance with an embodiment.

FIG. 2B is a cross-sectional illustration of the resonant antenna with the dielectric puck over a dielectric plate, in accordance with an embodiment.

FIG. 3A is a plan view illustration of a resonant antenna with a dielectric puck that comprises an electrically conductive insert, in accordance with an embodiment.

FIG. 3B is a cross-sectional illustration of the resonant antenna with a dielectric puck that comprises an electrically conductive insert over a dielectric plate, in accordance with an embodiment.

FIG. 4A is a plan view illustration of a resonant antenna with a dielectric puck that comprises a non-uniform dielectric constant through a thickness of the dielectric puck, in accordance with an embodiment.

FIG. 4B is a cross-sectional illustration of the resonant antenna with a dielectric puck with a non-uniform dielectric constant through a thickness of the dielectric puck over a dielectric plate, in accordance with an embodiment.

FIG. 5A is a plan view illustration of a resonant antenna with a dielectric puck that comprises a non-uniform dielectric constant through a radial direction of the dielectric puck, in accordance with an embodiment.

FIG. 5B is a cross-sectional illustration of the resonant antenna with a dielectric puck with a non-uniform dielectric constant through a radial direction of the dielectric puck over a dielectric plate, in accordance with an embodiment.

FIG. 6A is a plan view illustration of a resonant antenna with a dielectric puck that comprises a non-uniform dielectric constant through a radial direction of the dielectric puck, in accordance with an embodiment.

FIG. 6B is a cross-sectional illustration of the resonant antenna with a dielectric puck with a non-uniform dielectric constant through a radial direction of the dielectric puck over a dielectric plate, in accordance with an embodiment.

FIG. 7A is a plan view illustration of a resonant antenna with a dielectric puck that comprises an electrically conductive insert, in accordance with an embodiment.

FIG. 7B is a cross-sectional illustration of the resonant antenna with a dielectric puck that comprises an electrically conductive insert over a dielectric plate, in accordance with an embodiment.

FIG. 8A is a plan view illustration of a resonant antenna with a dielectric puck that comprises an off-center hole and a plurality of voids, in accordance with an embodiment.

FIG. 8B is a plan view illustration of the resonant antenna with a dielectric puck that comprises an off-center hole and a plurality of voids over a dielectric plate, in accordance with an embodiment.

FIG. 9 is a cross-sectional illustration of a plasma processing tool that comprises an array of resonant antennas, in accordance with an embodiment.

FIG. 10 illustrates a block diagram of an exemplary computer system that may be used in conjunction with a processing tool, in accordance with an embodiment.

### DETAILED DESCRIPTION

Embodiments described herein include apparatuses and methods for providing broadband microwave resonant antennas for plasma processing operations. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, existing microwave plasma sources are limited by a narrow process window that is tailored to a specific plasma species and a small range of processing variables. This limited range is due, at least in part, to the reliance of a single resonance mode in the resonant antenna of the microwave plasma source. For example, the TM01 mode is typically the only resonance mode that is within the operating frequency of the plasma. Optimization of resonant antenna geometry and material selection can only provide a certain amount of tailoring of the resonant antenna in order to provide a wider bandwidth of operation.

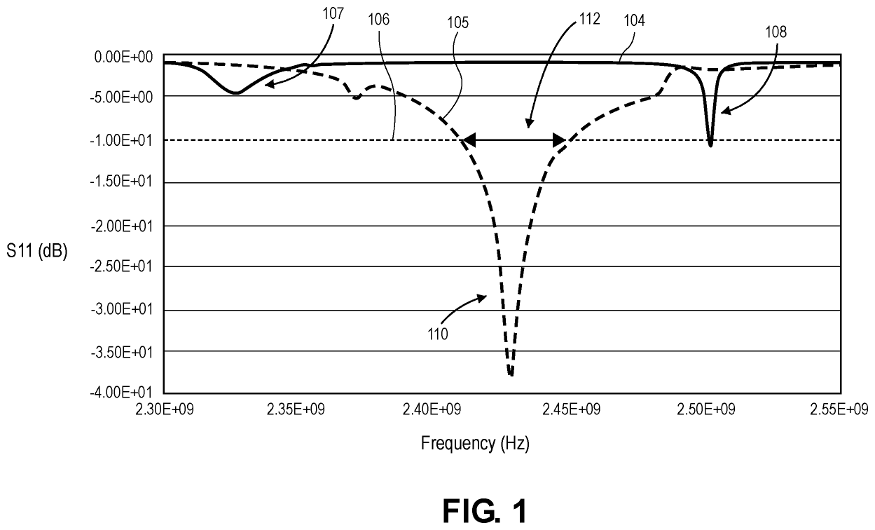

Referring now to FIG. 1, a graph of the reflection coefficient S11 of an existing resonant antenna 104 for a microwave plasma source compared to a resonant antenna 105 for a microwave plasma source in accordance with embodiments described herein is shown. As shown, the existing resonant antenna 104 may comprise a first resonance point 107 and a second resonance point 108. However, the first resonance point 107 is outside of the operational frequency range of the microwave plasma (e.g., between approximately 2.4 GHz and approximately 2.5 GHz). As such, only the second resonance point 108 contributes to the system. However, as shown, the bandwidth at an S11parameter of −10 dB (at line 106) is incredibly small (e.g., up to several megahertz). This minimal bandwidth is what limits the flexibility of the microwave plasma power source to accommodate different processing conditions.

Accordingly, embodiments disclosed herein include a resonant antenna that is capable of supporting at least two resonant modes within the operational frequency range of the microwave plasma. Further, design of the resonant antenna is made such that the two resonant modes are brought close together. As the spacing between the two resonant modes decreases, the two resonant modes will merge together to form a single large resonance point 110. In an embodiment, the resonance modes may comprise the TM01 mode and the TM02 mode.

As shown, in FIG. 1, the combined resonance point 110 has a significantly broader bandwidth 112 at the −10 dB S11 parameter. For example, the bandwidth 112 may be at least twice the bandwidth of resonant point 108, at least five times the bandwidth of resonant point 108, or at least ten times the bandwidth of resonant point 108. For example, the bandwidth 112 may be approximately 15 MHz or greater, approximately 25 MHz or greater, approximately 50 MHz or greater, or approximately 100 MHz or greater.

The wide bandwidth 112 allows for significant flexibility in tool deployment and/or process design. For example, a single resonant antenna structure may be used in a variety of different processing tools, such as, a plasma enhanced chemical vapor deposition (PECVD) tool, a plasma enhanced atomic layer deposition (PEALD) tool, a plasma treatment tool, a plasma cleaning tool, or any other tool that uses a plasma for some purpose. Such tools are useful for semiconductor processing environments. Though, microwave plasma resonant antennas in accordance with embodiments disclosed herein may be used in many different industries or application spaces.

In one embodiment, microwave plasma resonant antennas with merged resonance modes are made by optimizing a dielectric constant throughout the dielectric resonator. For example, a dielectric puck may generally comprise a cylindrical dielectric puck of material. However, instead of using a monolithic material with a single dielectric constant, embodiments use a multi-region approach. For example, a first region may have a first dielectric constant that supports a first resonant mode and a second region may have a second dielectric constant (that is different than the first dielectric constant) that supports a second resonant mode. While two different regions are used in some embodiments, it is to be appreciated that two or more regions, three or more regions, five or more regions, or ten or more regions may be used in order to provide a desired effect.

In one embodiment, the different regions are arranged in a vertical stack. That is, the dielectric constant changes in the Z-direction of the resonant antenna. Each of the regions may have a substantially uniform diameter in order to provide a single larger cylinder when stacked together. The regions may have the same thicknesses or different thicknesses.

In another embodiment, the different regions are arranged radially. That is, each region may comprise a shell, and the multiple shells may be concentric with each other. That is, the dielectric constant may change along a radial direction of the resonant antenna. In an embodiment, each region may have the same shell thickness. In other embodiments, the regions may have different shell thicknesses. The shells may directly contact each other, or a gap may be provided between each of the shells.

In another embodiment, microwave plasma resonant antennas with merged resonance modes are made by providing a recess into the dielectric resonator. The recess may be a ring that is formed into a top surface of the dielectric resonator. The recess may extend partially through a thickness of the dielectric resonator, or the recess may extend entirely through a thickness of the dielectric resonator. The recess may segregate the resonance mode formation to an inner region (surrounded by the recess) and an outer region (outside of the recess). In some embodiments, the recess is left with a gap. In other embodiments, the recess is filled with an electrically conductive insert. The electrically conductive insert may be left electrically floating, or the electrically conductive insert may be grounded.

In yet another embodiment, the microwave plasma resonant antennas with merged resonance modes are made through the formation of voids into the top surface of the resonant antennas. The voids may be regions with low dielectric constant material (e.g., air) that modifies the performance of the resonant antenna. In some embodiments, the voids may be circular voids that pass partially through a thickness of the dielectric resonator or entirely through the thickness of the dielectric resonator. Embodiments may also modify resonance behavior by providing the hole for the antenna rod off-center on the top surface of the resonant antenna.

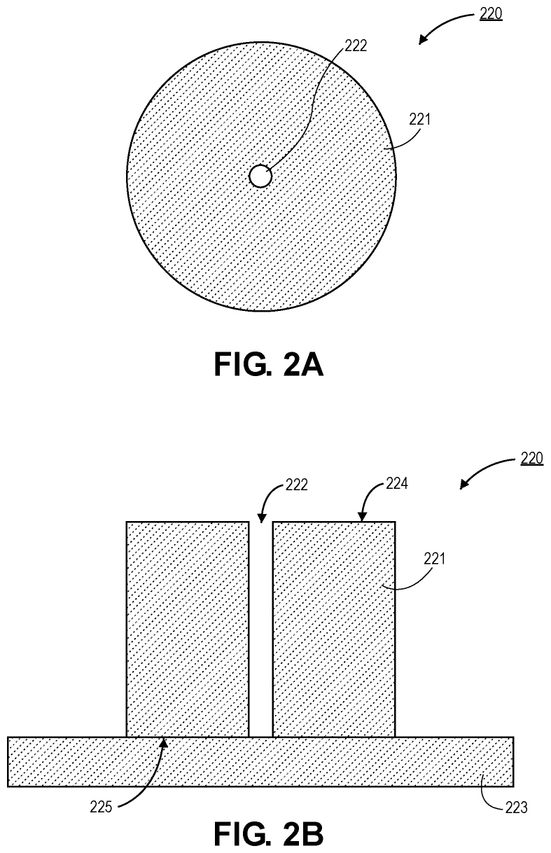

Referring now to FIGS. 2A and 2B, a pair of illustrations depicting a general structure for a dielectric resonator 220 that can be used for a microwave plasma source is shown, in accordance with an embodiment. In the embodiments shown in FIGS. 2A and 2B, the internal components of the dielectric resonator 220 are shown. However, it is to be appreciated that a housing (e.g., a metallic housing) may be provided around some or all of the dielectric resonator 220.

Referring now to FIG. 2A, a plan view illustration of a dielectric resonator 220 is shown, in accordance with an embodiment. In an embodiment, the dielectric resonator 220 may comprise a dielectric puck 221. The dielectric puck 221 may be cylindrical in some embodiments. Though, other shaped dielectric pucks 221 may also be used in some embodiments. A hole 222 may be provided through a thickness of the dielectric puck 221. The hole 222 is sized to accommodate an electrically conductive rod (not shown) used to transmit the microwave power into the system. The hole 222 may pass entirely through a thickness of the dielectric puck 221, or the hole 222 may pass partially through a thickness of the dielectric puck 221. The hole 222 may be centered with the dielectric puck 221.

Referring now to FIG. 2B, a cross-sectional illustration of the dielectric resonator 220 is shown, in accordance with an additional embodiment. In an embodiment, the dielectric puck 221 may have a top surface 224 and a bottom surface 225. In an embodiment, the bottom surface 225 may be provided on a dielectric plate 223. The dielectric plate 223 may be the same dielectric material as the dielectric puck 221. Though, in other embodiments, the dielectric plate 223 may be a different material than the dielectric puck 221. In some embodiments, the dielectric puck 221 is secured to the dielectric plate 223 by a housing (not shown) around the dielectric resonator 220.

The dielectric puck 221 may have any suitable form factor. The dimensions of the dielectric puck 221 may be chosen based, at least in part, on the dielectric constant of the dielectric puck 221. In an embodiment, the dielectric puck 221 may have a thickness (from the top surface 224 to the bottom surface 225) that is approximately 10 mm or greater, approximately 25 mm or greater, or approximately 50 mm or greater. A diameter of the dielectric puck 221 may be approximately 10 mm or greater, approximately 25 mm or greater, or approximately 50 mm or greater. In an embodiment, the dielectric plate 223 may have a diameter (or width) that is larger than the diameter of the dielectric puck 221. For example, the dielectric plate 223 may have a width of approximately 50 mm or greater, approximately 100 mm or greater, or approximately 200 mm or greater. A thickness of the dielectric plate 223 may be approximately 2 mm or greater, approximately 5 mm or greater, approximately 15 mm or greater, or approximately 30 mm or greater. As used herein, “approximately” may refer to a range of values that are within ten percent of the stated value. For example, approximately 100 mm may refer to a range between 90 mm and 110 mm.

In an embodiment, the dielectric resonator 220 has a uniform dielectric constant throughout the dielectric puck 221. In such an embodiment, a single resonance mode may be supported. As such, a behavior similar to the behavior depicted by the line for an existing resonant antenna 104 in FIG. 1 may be provided. That is, a bandwidth of the dielectric resonator 220 may not be wide enough to support large process windows.

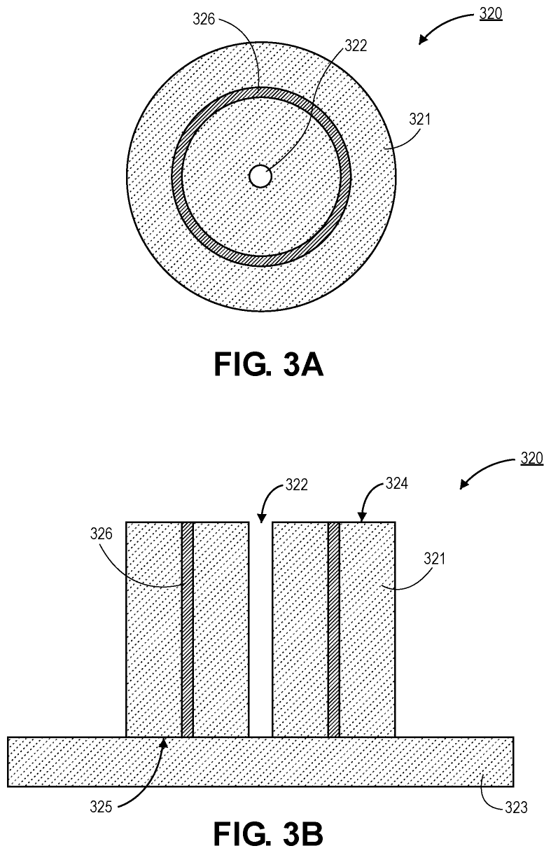

Referring now to FIGS. 3A and 3B, a pair of illustrations depicting a general structure for a dielectric resonator 320 that can be used for a microwave plasma source is shown, in accordance with an embodiment. In the embodiments shown in FIGS. 3A and 3B, the internal components of the dielectric resonator 320 are shown. However, it is to be appreciated that a housing (e.g., a metallic housing) may be provided around some or all of the dielectric resonator 320.

Referring now to FIG. 3A, a plan view illustration of the dielectric resonator 320 is shown, in accordance with an embodiment. In an embodiment, the dielectric resonator 320 may be similar to the dielectric resonator 220 in FIG. 2A, with the exception of the construction of the dielectric puck 321. In an embodiment, the dielectric puck 321 may comprise a dielectric material with a dielectric constant that is substantially uniform throughout a volume of the dielectric puck 321. In an embodiment, a hole 322 may be provided through (or partially through) a thickness of the dielectric puck 321.

In an embodiment, an insert 326 may be provided within the dielectric puck 321. The insert 326 may be an electrically conductive material. For example, the insert 326 may comprise copper, aluminum, or the like. In an embodiment, the insert 326 is a ring-shaped insert that surrounds the hole 322. The insert 326 may be electrically floating, or the insert 326 is configured to be grounded.

In an embodiment, the insert 326 may be used to divide the dielectric puck 321 into an inner region and an outer region. The inner region may support a first resonance mode, and the outer region may support a second resonance mode. The inner diameter of the insert 326 may be chosen in order to match resonant characteristics of the particular resonance mode. In some embodiments, the inner diameter of the insert 326 may be up to 80% of a diameter of the dielectric puck 321, up to 50% of a diameter of the dielectric puck 321, or up to 25% of a diameter of the dielectric puck 321. Though, larger diameters may also be used in some embodiments.

Referring now to FIG. 3B, a cross-sectional illustration of the dielectric resonator 320 is shown, in accordance with an embodiment. As shown, the insert 326 extends through an entire thickness of the dielectric puck 321 from a top surface 324 to a bottom surface 325. Additionally, the bottom surface 325 may be supported by a dielectric plate 323. The dielectric plate 323 may be similar to the dielectric plate 223 described in greater detail above.

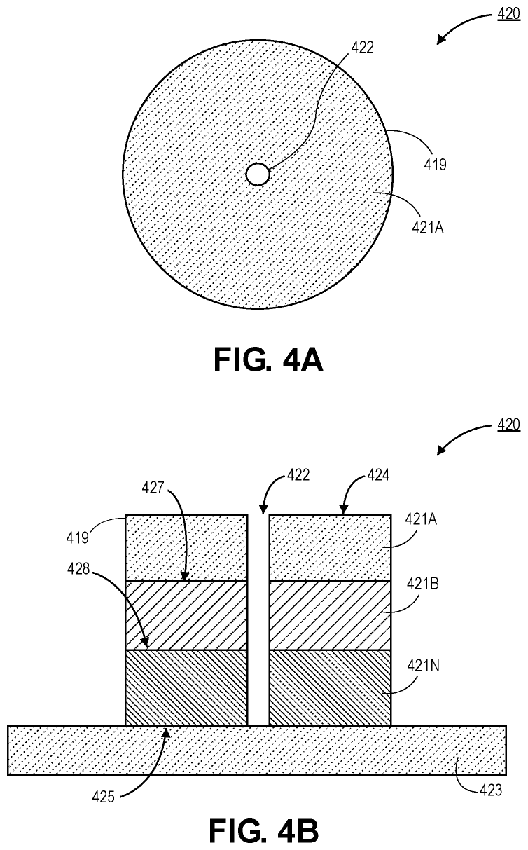

Referring now to FIGS. 4A and 4B, a pair of illustrations depicting a general structure for a dielectric resonator 420 that can be used for a microwave plasma source is shown, in accordance with an embodiment. In the embodiments shown in FIGS. 4A and 4B, the internal components of the dielectric resonator 420 are shown. However, it is to be appreciated that a housing (e.g., a metallic housing) may be provided around some or all of the dielectric resonator 420.

Referring now to FIG. 4A, a plan view illustration of the dielectric resonator 420 is shown, in accordance with an embodiment. In an embodiment, the dielectric resonator 420 may be similar to the dielectric resonator 220 in FIG. 2A, with the exception of the construction of the dielectric puck 419. For example, the dielectric puck 419 may be cylindrical with a hole 422 at a center of the cylinder. The hole 422 may pass through (or partially through a thickness of the dielectric puck 419). However, instead of a single monolithic piece of dielectric material, the dielectric puck 419 may comprise a plurality of dielectric regions 421A-421N, as shown in FIG. 4B.

Referring now to FIG. 4B, a cross-sectional illustration of the dielectric resonator 420 is shown, in accordance with an embodiment. As shown, three dielectric regions 421A-421N are shown in FIG. 4B. However, it is to be appreciated that the number of dielectric regions 421A-421N of the dielectric puck 419 may comprise two or more regions 421, three or more regions 421, five or more regions 421, or ten or more regions 421. In an embodiment, each dielectric region 421A-421N may have the same diameter in order to provide a uniform cylindrical shape for the dielectric puck 419. In an embodiment, the regions 421 have a uniform thickness. In other embodiments, the regions 421 have a non-uniform thickness.

In an embodiment, each dielectric region 421 may have a different dielectric constant. For example, the dielectric constants may increase with increasing distance from the dielectric plate 423 (e.g., so that a dielectric constant at a top surface 424 is the highest), or the dielectric constant may decrease with increasing distance from the dielectric plate 423 (e.g., so that a dielectric constant at a bottom surface 425 is the highest). In some embodiments, a middle dielectric region 421 may have a higher dielectric constant than both the bottommost dielectric region 421 and the top most dielectric region 421. The different dielectric constants may be provided through the use of different dielectric materials. In some embodiments, the different dielectric materials may comprise the same elements with different element concentrations. In other embodiments, materials with different elements may be used.

In an embodiment, the dielectric regions 421 may be supported on each other and in direct contact with each other. For example, at interface 427, dielectric region 421A directly contacts dielectric region 421B, and at interface 428, dielectric region 421B directly contacts dielectric region 421N. Though, in other embodiments an interface material (not shown) may be provided between dielectric regions 421 (e.g., as an adhesive or the like). Additionally, the bottom surface 425 may be supported by a dielectric plate 423. The dielectric plate 423 may be similar to the dielectric plate 223 described in greater detail above.

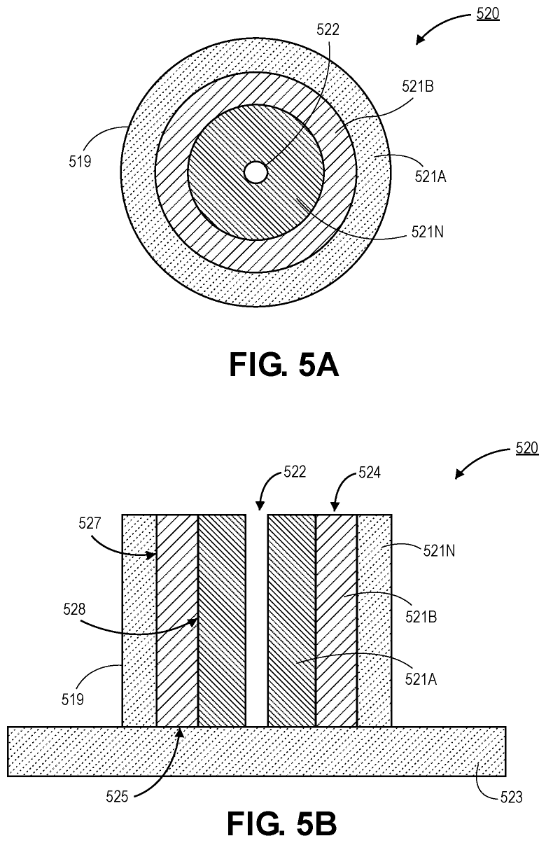

Referring now to FIGS. 5A and 5B, a pair of illustrations depicting a general structure for a dielectric resonator 520 that can be used for a microwave plasma source is shown, in accordance with an embodiment. In the embodiments shown in FIGS. 5A and 5B, the internal components of the dielectric resonator 520 are shown. However, it is to be appreciated that a housing (e.g., a metallic housing) may be provided around some or all of the dielectric resonator 520.

Referring now to FIG. 5A, a plan view illustration of the dielectric resonator 520 is shown, in accordance with an embodiment. In an embodiment, the dielectric resonator 520 may be similar to the dielectric resonator 220 in FIG. 2A, with the exception of the construction of the dielectric puck 519. For example, the dielectric puck 519 may be cylindrical with a hole 522 at a center of a top surface 524 of the cylinder. The hole 522 may pass through (or partially through a thickness of the dielectric puck 519). However, instead of a single monolithic piece of dielectric material, the dielectric puck 519 may comprise a plurality of dielectric regions 521A-521N.

Referring now to FIG. 5B, a cross-sectional illustration of the dielectric resonator 520 is shown, in accordance with an embodiment. As shown, three dielectric regions 521A-521N are shown in FIG. 5B. However, it is to be appreciated that the number of dielectric regions 521A-521N of the dielectric puck 519 may comprise two or more regions 521, three or more regions 521, five or more regions 521, or ten or more regions 521. In an embodiment, each dielectric region 521A-521N are shells that are arranged in a concentric manner about the hole 522. In an embodiment, the regions 521 have a uniform thickness (i.e., a thickness between an outer diameter and an inner diameter of each shell). In other embodiments, the regions 521 have a non-uniform thickness.

As used herein, a “shell” may refer to a structure with an inner dimension (e.g., an inner diameter) and an outer dimension (e.g., an outer diameter). That is, the shell may have a hole or path provided between a top surface and a bottom surface of the shell. A shell may be placed around a second structure so that the second structure is positioned within the hole of the shell. The shell may cover a portion of (or all of) a sidewall surface of the second structure. The shell may have an open top and/or an open bottom. In this way, the shell may not fully surround the second structure (i.e., covering the sidewalls, the top surface, and the bottom surface of the second structure). In other embodiments, the shell may have a closed top and/or a closed bottom so that a top surface and/or a bottom surface of the second structure is covered by the shell as well.

In an embodiment, each dielectric region 521 may have a different dielectric constant. For example, the dielectric constants may increase with increasing distance from the hole 522 in a radial direction (e.g., so that a dielectric constant at an outer edge of the dielectric puck 519 is the highest), or the dielectric constant may decrease with increasing distance from the hole 522 (e.g., so that a dielectric constant at the hole 522 is the highest). In some embodiments, a middle dielectric region 521B may have a higher dielectric constant than both the innermost dielectric region 521A and the outer most dielectric region 521N. The different dielectric constants may be provided through the use of different dielectric materials. In some embodiments, the different dielectric materials may comprise the same elements with different element concentrations. In other embodiments, materials with different elements may be used.

In an embodiment, the dielectric regions 521 may be in direct contact with each other. For example, at interface 527, dielectric region 521N directly contacts dielectric region 521B, and at interface 528, dielectric region 521B directly contacts dielectric region 521A. Though, in other embodiments an interface material (not shown) may be provided between dielectric regions 521 (e.g., as an adhesive or the like). Additionally, the bottom surface 525 may be supported by a dielectric plate 523. The dielectric plate 523 may be similar to the dielectric plate 223 described in greater detail above.

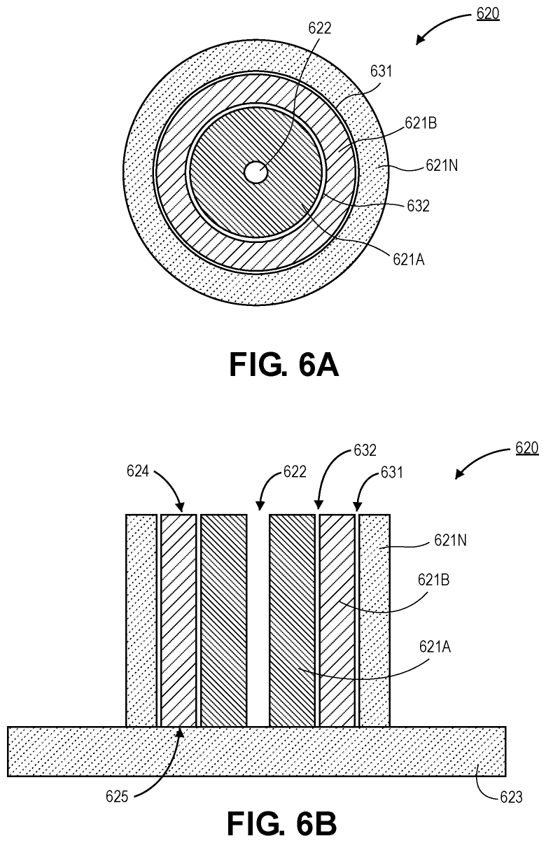

Referring now to FIGS. 6A and 6B, a pair of illustrations depicting a general structure for a dielectric resonator 620 that can be used for a microwave plasma source is shown, in accordance with an embodiment. In the embodiments shown in FIGS. 6A and 6B, the internal components of the dielectric resonator 620 are shown. However, it is to be appreciated that a housing (e.g., a metallic housing) may be provided around some or all of the dielectric resonator 620.

In an embodiment, the dielectric resonator 620 may be similar to the dielectric resonator 520 described above, with the exception of the interfaces between the dielectric regions 621. Instead of being in direct contact with each other, the dielectric regions 621 are spaced apart from each other by a gap. For example, gap 631 is provided between dielectric region 621B and dielectric region 621N, and gap 632 is provided between dielectric region 621A and dielectric region 621B.

As shown in FIG. 6B, the gaps 631 and 632 may extend from a top surface 624 through an entire thickness of the dielectric resonator 620 to a bottom surface 625. In other embodiments, the gaps 631 and 632 may not pass entirely through a thickness of the dielectric resonator. The gaps 631 and 632 may have sidewalls that are substantially parallel to sidewalls of the hole 622. In the illustrated embodiment, the gaps 631 and 632 are air filled (or filled with another gas). In other embodiments, the gaps 631 and 632 may be filled with an electrically conductive insert, such as a copper insert, an aluminum insert, or the like. Additionally, the bottom surface 625 may be supported by a dielectric plate 623. The dielectric plate 623 may be similar to the dielectric plate 223 described in greater detail above.

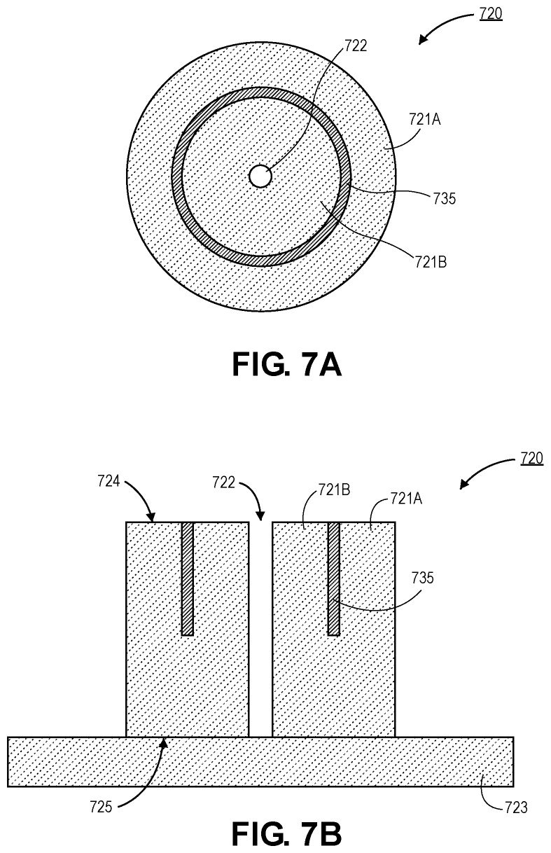

Referring now to FIGS. 7A and 7B, a pair of illustrations depicting a general structure for a dielectric resonator 720 that can be used for a microwave plasma source is shown, in accordance with an embodiment. In the embodiments shown in FIGS. 7A and 7B, the internal components of the dielectric resonator 720 are shown. However, it is to be appreciated that a housing (e.g., a metallic housing) may be provided around some or all of the dielectric resonator 720.

Referring now to FIG. 7A, a plan view illustration of the dielectric resonator 720 is shown, in accordance with an embodiment. In an embodiment, the dielectric resonator 720 may be similar to the dielectric resonator 220 in FIG. 2A, with the exception of the construction of the dielectric puck 721. In an embodiment, the dielectric puck 721 may comprise a dielectric material with a dielectric constant that is substantially uniform throughout a volume of the dielectric puck 721. In an embodiment, a hole 722 may be provided through (or partially through) a thickness of the dielectric puck 721.

In an embodiment, an insert 735 may be provided within the dielectric puck 721. The insert 735 may be an electrically conductive material. For example, the insert 735 may comprise copper, aluminum, or the like. In an embodiment, the insert 735 is a ring-shaped insert that surrounds the hole 722. The insert 735 may be electrically floating, or the insert 735 is configured to be grounded.

In an embodiment, the insert 735 may be used to divide the dielectric puck 721 into an inner region 721B and an outer region 721A. The inner region 721B may support a first resonance mode, and the outer region 721A may support a second resonance mode. The inner diameter of the insert 735 may be chosen in order to match resonant characteristics of the particular resonance mode. In some embodiments, the inner diameter of the insert 735 may be up to 80% of a diameter of the dielectric puck 721, up to 50% of a diameter of the dielectric puck 721, or up to 25% of a diameter of the dielectric puck 721. Though larger diameters may also be used in some embodiments.

Referring now to FIG. 7B, a cross-sectional illustration of the dielectric resonator 720 is shown, in accordance with an embodiment. As shown, the insert 735 extends partially through a thickness of the dielectric puck 721 from a top surface 724 towards a bottom surface 725. In an embodiment, the insert 735 has a height that is up to 25% of the height of the dielectric puck 721, up to 50% of the height of the dielectric puck 721, or up to 90% of the height of the dielectric puck 721. Though, insert 735 may extend to any percentage of the height of the dielectric puck 721 that is less than 100%. Additionally, the bottom surface 725 may be supported by a dielectric plate 723. The dielectric plate 723 may be similar to the dielectric plate 223 described in greater detail above.

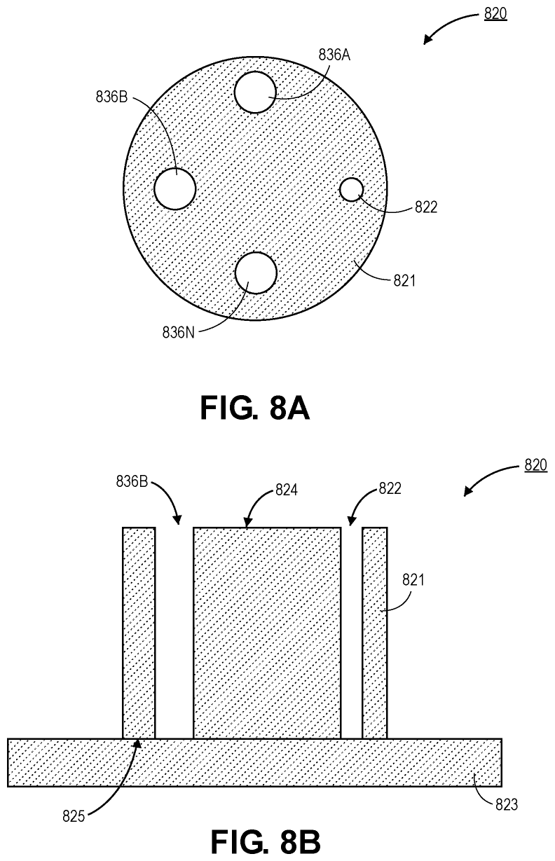

Referring now to FIGS. 8A and 8B, a pair of illustrations depicting a general structure for a dielectric resonator 820 that can be used for a microwave plasma source is shown, in accordance with an embodiment. In the embodiments shown in FIGS. 8A and 8B, the internal components of the dielectric resonator 820 are shown. However, it is to be appreciated that a housing (e.g., a metallic housing) may be provided around some or all of the dielectric resonator 820.

Referring now to FIG. 8A, a plan view illustration of the dielectric resonator 820 is shown, in accordance with an embodiment. In an embodiment, the dielectric resonator 820 may be similar to the dielectric resonator 820 in FIG. 2A, with the exception of the construction of the dielectric puck 821. Instead of having a hole 822 that is formed at a center of the dielectric puck 821, the hole 822 may be off-center from the top surface of the dielectric puck 821. For example, in FIG. 8A the hole 822 is toward a right edge of the dielectric puck 821.

Additionally, one or more voids 836A-836N may be provided into the dielectric puck 821. The voids 836 may be circular or any other suitable shape (e.g., square, rectangular, triangular, ring-shaped, etc.). In an embodiment, a diameter of the voids 836 may be larger than a diameter of the hole 822. The voids 836 are used to provide areas of low dielectric constant material (e.g., air or other gas) within the dielectric puck 821. By choosing proper locations and geometries for the voids 836, multiple resonance modes can be obtained in order to obtain the desired process design flexibility for the dielectric resonator 820.

Referring now to FIG. 8B, a cross-sectional illustration of the dielectric resonator 820 is shown, in accordance with an embodiment. As shown, the voids 836 and the hole 822 may extend from a top surface 824 of the dielectric puck 821 to a bottom surface 825 of the dielectric puck 821. Though, voids 836 and/or hole 822 may be formed to any desired depth within the dielectric puck 821. Additionally, the bottom surface 825 may be supported by a dielectric plate 823. The dielectric plate 823 may be similar to the dielectric plate 223 described in greater detail above.

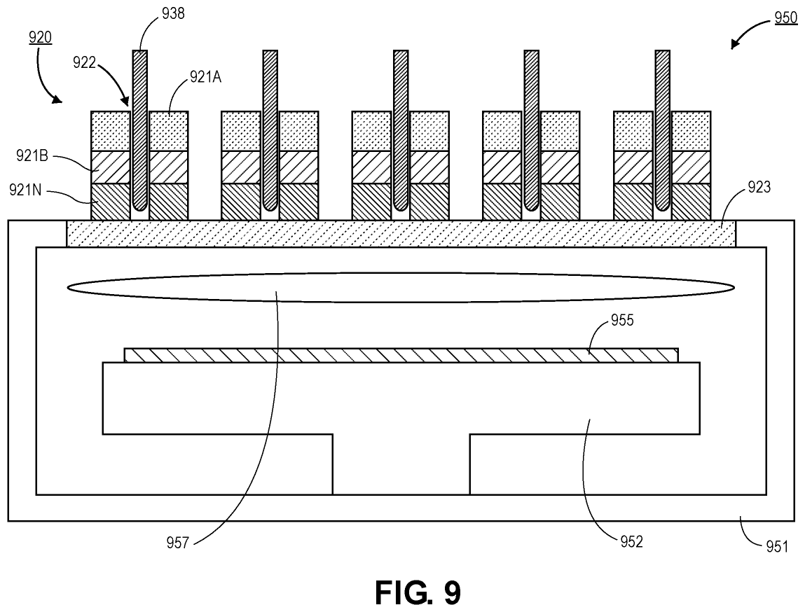

Referring now to FIG. 9, a cross-sectional illustration of a plasma tool 950 is shown, in accordance with an embodiment. In an embodiment, the plasma tool 950 may be a PECVD tool, a PEALD tool, a plasma treatment tool, or any other tool that uses a plasma. In some embodiments, a remote microwave plasma source may also be used for the plasma tool 950. In an embodiment, the plasma tool 950 comprises a chamber 951 suitable for maintaining a plasma 957. The chamber 951 may be referred to as a vacuum chamber. An exhaust line (not shown) is used to pump down the pressure. One or more gas feed lines (not shown) may inject gas into the chamber through a showerhead or the like. In an embodiment, a pedestal 952 is provided in the chamber 951. The pedestal 952 may comprise an electrostatic chuck (ESC) or the like for securing a substrate 955. The substrate 955 may be a semiconductor substrate, such as a silicon wafer.

In an embodiment, the plasma source may comprise one or more resonant antennas that comprise a dielectric resonator 920 and an electrically conductive rod 938 that is inserted into a hole 922 in the dielectric resonator 920. The rod 938 may be electrically coupled to a power supply (not shown) in order to provide microwave power to the rod 938. In an embodiment, the dielectric resonator 920 may be similar to any of the dielectric resonators described in greater detail herein. For example, the dielectric resonator 920 may be designed to support two resonance modes. As described above, this enables a wider processing window for the plasma tool 950.

In the particular embodiment shown in FIG. 9, the dielectric resonator 920 has a construction similar to the dielectric resonator 420 in FIGS. 4A and 4B. That is, a multi-region 921A-921N structure with a vertically dependent dielectric constants are used to enable the support of two resonance modes. Shell-based regions may also be used in some embodiments. Insert based approaches, voiding, and/or off-center holes 922 may also be used in some embodiments.

In an embodiment, the dielectric resonators 920 may be supported on a dielectric plate 923 that is opposite from the pedestal 952. The dielectric plate 923 may be similar to any of the dielectric plates described in greater detail herein. In the embodiment shown in FIG. 9, a plurality of dielectric resonators 920 are supported by the same dielectric plate 923.

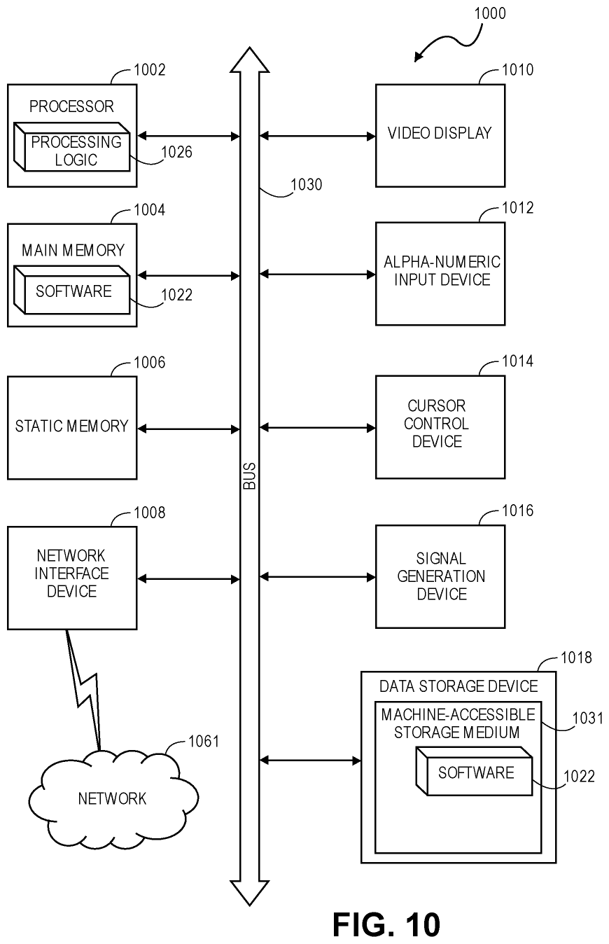

Referring now to FIG. 10, a block diagram of an exemplary computer system 1000 of a processing tool is illustrated in accordance with an embodiment. In an embodiment, computer system 1000 is coupled to and controls processing in the processing tool. Computer system 1000 may be connected (e.g., networked) to other machines in a Local Area Network (LAN), an intranet, an extranet, or the Internet. Computer system 1000 may operate in the capacity of a server or a client machine in a client-server network environment, or as a peer machine in a peer-to-peer (or distributed) network environment. Computer system 1000 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1000, the term “machine” shall also be taken to include any collection of machines (e.g., computers) that individually or jointly execute a set (or multiple sets) of instructions to perform any one or more of the methodologies described herein.

Computer system 1000 may include a computer program product, or software 1022, having a non-transitory machine-readable medium having stored thereon instructions, which may be used to program computer system 1000 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1000 includes a system processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

System processor 1002 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1002 may also be one or more special-purpose processing devices such as an application specific integrated circuit (ASIC), a field programmable gate array (FPGA), a digital signal system processor (DSP), network system processor, or the like. System processor 1002 is configured to execute the processing logic 1026 for performing the operations described herein.

The computer system 1000 may further include a system network interface device 1008 for communicating with other devices or machines. The computer system 1000 may also include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium 1031 (or more specifically a computer-readable storage medium) on which is stored one or more sets of instructions (e.g., software 1022) embodying any one or more of the methodologies or functions described herein. The software 1022 may also reside, completely or at least partially, within the main memory 1004 and/or within the system processor 1002 during execution thereof by the computer system 1000, the main memory 1004 and the system processor 1002 also constituting machine-readable storage media. The software 1022 may further be transmitted or received over a network 1061 via the system network interface device 1008. In an embodiment, the network interface device 1008 may operate using RF coupling, optical coupling, acoustic coupling, or inductive coupling.

While the machine-accessible storage medium 1031 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a dielectric puck, wherein the dielectric puck has a cylindrical shape, and wherein the dielectric puck comprises:
a first region with a first dielectric constant; and
a second region with a second dielectric constant that is different than the first dielectric constant; and
a hole into a top surface of the dielectric puck.

2. The apparatus of claim 1, wherein the first region is a first cylinder and the second region is second cylinder that is positioned over the first region.

3. The apparatus of claim 1, wherein the first region is a first shell and the second region is a second shell around the first region.

4. The apparatus of claim 3, wherein the first region directly contacts the second region.

5. The apparatus of claim 3, wherein the first region is spaced apart from the second region.

6. The apparatus of claim 1, wherein the hole is at a center of the top surface of the dielectric puck.

7. The apparatus of claim 1, wherein the hole is off-center of the top surface of the dielectric puck.

8. The apparatus of claim 1, further comprising:
a second hole into the top surface of the dielectric puck, wherein a diameter of the second hole is larger than a diameter of the hole.

9. The apparatus of claim 1, wherein the hole passes through an entire thickness of the dielectric puck.

10. The apparatus of claim 1, wherein the dielectric puck further comprises:
a third region with a third dielectric constant that is different than the first dielectric constant and the second dielectric constant.

11. An apparatus, comprising:
a dielectric puck, wherein the dielectric puck has a cylindrical shape;
a recess into a top surface of the dielectric puck, wherein the recess is ring shaped and defines an inner region of the dielectric puck and an outer region of the dielectric puck; and
a hole into the top surface of the dielectric puck, wherein the recess surrounds the hole.

12. The apparatus of claim 11, wherein the recess is filled with an electrically conductive insert.

13. The apparatus of claim 12, wherein the electrically conductive insert is configured to be grounded or floating.

14. The apparatus of claim 11, wherein a depth of the recess is less than a thickness of the dielectric puck.

15. The apparatus of claim 11, wherein the recess passes through an entire thickness of the dielectric puck.

16. The apparatus of claim 11, wherein the dielectric puck has a non-uniform dielectric constant through a thickness of the dielectric puck or radially through the dielectric puck.

17. A plasma processing tool, comprising:
a chamber;
a pedestal in the chamber;
a dielectric plate opposite from the pedestal;
a dielectric puck over the dielectric plate, wherein the dielectric puck comprises:
a material composition with a non-uniform dielectric constant in a radial direction and/or a thickness direction; and
a hole into the dielectric puck; and
an electrically conductive rod inserted into the hole.

18. The plasma processing tool of claim 17, further comprising:
a plurality of dielectric pucks over the dielectric plate.

19. The plasma processing tool of claim 17, wherein an impedance bandwidth of an antenna comprising the dielectric puck and the electrically conductive rod is at least 25 MHz at an S11 parameter of −10 dB.

20. The plasma processing tool of claim 17, wherein an antenna comprising the dielectric puck and the electrically conductive rod operates in a first resonance mode and a second resonance mode.
